(19) United States
(12) Patent Application Publication
(10) Pub. No.: US 2025/0112585 A1
(43) Pub. Date: Apr. 3, 2025

(54) HEMISPHERICAL SOLAR PANEL FOR ENHANCED LIGHT ABSORPTION

(71) Applicant: Abbas Rashidi Dizajgan, Arnold, MD (US)

(72) Inventor: Abbas Rashidi Dizajgan, Arnold, MD (US)

(21) Appl. No.: 18/977,806

(22) Filed: Dec. 11, 2024

Related U.S. Application Data
(63) Continuation-in-part of application No. 18/610,913, filed on Apr. 8, 2024.
(60) Provisional application No. 63/462,983, filed on Apr. 29, 2023.

(51) Int. Cl. H02S 20/20; E04B 1/30; E04B 1/32

(52) U.S. Cl. CPC H02S 20/20; E04B 1/30; E04B 1/3211; E04B 2001/3252; E04B 2001/3294

(57) ABSTRACT

A photovoltaic panel having a flat substrate with at least one hemispherical shaped structure positioned on the flat substrate, and a plurality of solar cells are adhered to and cover hemispherical shaped structure is presented. Utilizing a hemispherical-shape with the diameter of the original length of the supporting substrate will provide a 57% increase in the surface area available to collect solar radiation with an accompanying increase in the energy generated.

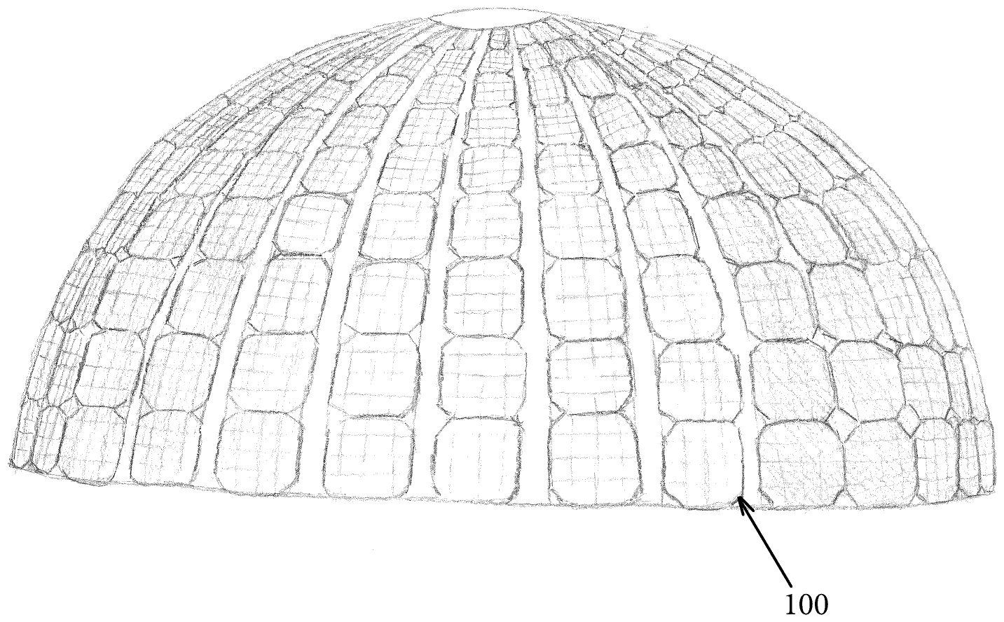

### RELATED APPLICATIONS

The present application claims benefit from earlier filed U.S. application Ser. No. 18/610,913, filed Apr. 8, 2024, which claims benefit from earlier filed U.S. Provisional Application No. 63/462,983, filed Apr. 29, 2023, the disclosures of both applications are incorporated by reference in their entireties for all purposes.

### BACKGROUND

### Field of Invention

The present disclosure relates to hemispherical solar cell and solar panel incorporating the solar cell to provide increased solar energy conversion and electrical energy generation efficiencies.

### Discussion of the Related Art

There are millions of photovoltaic panels distributed around the world as mankind moves from non-renewable sources of energy to more planet friendly renewable energy sources. All of these panels are formed on flat pieces of silicon-based substrates and are thus limited in the amount of sunlight striking on the solar collecting and energy generating cells in a manner that allows for conversion of the solar radiation to electricity. Many of these existing photovoltaic panels exhibit low power generation efficiency, require difficult and space consuming electrical connections, and typically face only one direction with respect to the sun.

A structure that would allow for a higher percentage of the impinging solar radiation to be converted into electricity would be of great interest to solar energy producers and developers of solar energy generators.

### SUMMARY OF THE DISCLOSURE

The present disclosure features a photovoltaic panel comprising a flat substrate, at least one hemispherical shaped structure positioned on the flat substrate, and a plurality of solar cells, wherein the plurality of solar cells is adhered to and cover the at least one hemispherical shaped structure.

Further disclosed by the present application is a method of preparing a hemispherical-shaped solar panel including the steps of providing a hemispherical-shaped forming plate, and a sheet of support material, contacting the sheet of support material to the hemispherical-shaped forming plate, conforming the support material to the hemispherical-shaped forming plate, forming a hemispherical dome in the sheet of support based material, the hemispherical dome having an outer surface and an inner surface, adhering solar cells to the outer surface of the hemispherical dome, and electrically connecting the solar cells.

Additionally disclosed is a method of using a photovoltaic panel to generate electrical energy from the sun by providing a photovoltaic panel comprising a flat substrate, at least one hemispherical shaped structure positioned on the flat substrate, and a plurality of solar cells adhered to and covering the at least one hemispherical shaped structure, positioning the photovoltaic panel to expose it to the maximum possible amount of sunlight for its location, exposing the photovoltaic panel to sunlight, and generating electrical energy from the photovoltaic panel from sunrise to sunset.

### BRIEF DESCRIPTION OF THE FIGURES

The accompanying drawing(s), which are included to provide a further understanding of the invention and are incorporated in and constitute a part of this specification, illustrates preferred embodiments of the invention and together with the detailed description serve to explain the principles of the invention. In the drawing(s):

The FIGURE is a general illustration of one embodiment of a solar cell according to the present teachings.

Any dimensions provided in the FIGURE are for illustrative purposes and are not limiting. The provided FIGURE is to scale.

### DETAILED DESCRIPTION

Presently disclosed is a photovoltaic panel having a flat substrate with at least one hemispherical shaped structure positioned on the flat substrate, and a plurality of solar cells which is adhered to and covers the at least one hemispherical shaped structure.

The presently disclosed photovoltaic panel can have a round solar cell adhered at the top of the hemispherical shaped structure, and the solar cells, of whatever shape, can be connected together electronically.

In some embodiments of the presently disclosed photovoltaic panel, the hemispherical shaped structure has a maximum diameter equal to the length of a square flat substrate, and such an embodiment would have at least 57% more surface area than the flat substrate.

The photovoltaic panel disclosed herein can have both flat and round solar cells that are one of more member selected from the group consisting of monocrystalline silicon-based solar cells, polycrystalline silicon-based solar cells, perovskite-based solar cells, photovoltaic organic-based solar cells, thin film solar cells, cadmium telluride-based solar cells, and copper indium gallium selenide-based solar cells.

The presently disclosed photovoltaic panel can have a hemispherical shaped structure which can be composed of one or more material selected from the group consisting of silicon, polycarbonate, carbon fiber, aluminum, stainless steel, galvanized steel, fiberglass, composite materials, and titanium.

In some embodiments of the presently taught photovoltaic panel can further have a coating layer on the solar cells and an outer surface of the at least one hemispherical shaped structure. This coating layer can be ethylene-vinyl acetate.

In some embodiments of the presently disclosed photovoltaic panel, a plurality of hemispherical shaped structures can be positioned on the flat substrate. In such an embodiment of the presently disclosed photovoltaic panel, each one of the plurality of hemispherical shaped structures can have a plurality of solar cells adhered thereto.

The present application also discloses a method of preparing a hemispherical-shaped solar panel including the steps of providing a hemispherical-shaped forming plate, providing a sheet of support material, contacting the sheet of support material to the hemispherical-shaped forming plate, conforming the support material to the hemispherical-shaped forming plate, forming a hemispherical dome in the sheet of support based material, the hemispherical dome having an outer surface and an inner surface, adhering solar cells to the outer surface of the hemispherical dome, and electrically connecting the solar cells.

The above method further includes a step of coating the adhered solar cells and the outer surface of the hemispherical dome with a protective coating.

The presently taught method utilizes solar cells that are one of more member selected from the group consisting of monocrystalline silicon-based solar cells, polycrystalline silicon-based solar cells, perovskite-based solar cells, photovoltaic organic-based solar cells, thin film solar cells, cadmium telluride-based solar cells, and copper indium gallium selenide-based solar cells.

In one embodiment of the disclosed method the support material can be composed of one or more material selected from the group consisting of silicon, polycarbonate, carbon fiber, aluminum, stainless steel, galvanized steel, fiberglass, composite materials, and titanium.

In some methods according to the present teachings, a plurality of the hemispherical domes can be present on a hemispherical-shaped forming plate. This allows for the preparation of solar panels having a plurality of hemispherical domes.

In most embodiments of the present teachings, the produced hemispherical dome with adhered solar cells can be coated with a protective coating including a hydrophobic, scratch-resistant and self-cleaning coating. In some cases, the protective coating can be a waterproof and UV-resistant ethylene-vinyl acetate.

Another disclosure of the present application is a method of using a photovoltaic panel to generate electrical energy from the sun by providing a photovoltaic panel featuring a flat substrate, at least one hemispherical shaped structure positioned on the flat substrate, and a plurality of solar cells adhered to and covering the at least one hemispherical shaped structure, then positioning the photovoltaic panel to expose it to the maximum possible amount of sunlight for its location, exposing the photovoltaic panel to sunlight, and generating electrical energy from the photovoltaic panel.

In the above-disclosed method, the solar cells can include one of more member selected from the group consisting of monocrystalline silicon-based solar cells, polycrystalline silicon-based solar cells, perovskite-based solar cells, photovoltaic organic-based solar cells, thin film solar cells, cadmium telluride-based solar cells, and copper indium gallium selenide-based solar cells.

Also in the above-disclosed method, the hemispherical shaped structure can be composed of one or more material selected from the group consisting of silicon, polycarbonate, carbon fiber, aluminum, stainless steel, galvanized steel, fiberglass, composite materials, and titanium.

One embodiment of the presently disclosed photovoltaic panel is illustrated in the FIGURE with a plurality of solar cells 100, in this case, flat cells, adhered to the outer surface of a hemispherical-shaped support. There are vacant spaces running up the side of the hemispherical-shaped support between the rows of solar cells. Not shown are the electrical connections between the solar cells to gather the converted solar energy to electricity generated by the solar cells.

Solar panel and solar cell manufacturers and installers calculate the electrical output of a photovoltaic system, as disclosed herein, with this calculation:

$$E = A \times r \times H \times PR ,$$

where E is the energy output (KWh), A is the effective area of the panel (m²), r is the solar panel yield or efficiency (%), H is the annual average solar radiation (kWh/m²/day) on a standard flat solar panel, and PR is the performance ratio for a standard flat solar panel. These factors are described in more detail below.

According to the nominal practice in the solar panel and cell industry, the solar panel yield, r, is determined under standard test conditions (“STC”) of solar radiation=1000 W/m², cell temperature=25° C., wind speed=1 m/s, and AM=1.5. AM is air mass coefficient, a measure of the path length sunlight takes through the Earth's atmosphere before reaching the surface. The AM value of 1.5 is typically used as the standard to simulate the average solar radiation path length at the Earth's surface when the sun is at an angle of 48.2 degrees above the horizon. The unit of nominal power of a photovoltaic panel under STC is referred to as “Watt-peak.”

The performance ratio, PR, provides the efficiency of a solar panel installation independent of such factors as the azimuthal orientation and inclination of the solar panel. This value ranges between 0.5 to 0.9 with a nominal value of 0.75. The PR incorporates all system losses which are dependent on the site, size and technology utilized at the subject installation. Some sources of system loss include dust and shadows on the solar panel, temperature both low and high, transmission cables, and DC/AC inverter.

In some commercially known instances, the area of a flat square solar panel (each side measuring 1.27 m) is 1.61 m². In one example of the presently disclosed teachings, the area of a hemispherical panel with a footprint that fits within the footprint of the square panel, that is, having a diameter of 1.27 m (radius of 0.635 m) is 2.53 m².

Therefore in a flat area of 1.27 m by 1.27 m, if a hemispherical shaped is utilized, having a diameter of 1.27 m, than an increase in exposed area of 57% will be realized.

For reference, a standard residential solar panel has an overall efficiency of about 20%. For instance, a solar panel with an area of 1.27 m by 1.27 m typically produces 300 watts of electricity per hour. Using the formula of efficiency is equal to the power output of the panel divided by the product of the solar irradiance (in W/m²) and the area of the panel. For the above example, 300 W/(1000 W/m2×1.61 m2) is equal to 18.63% efficiency. If a hemispherical solar cell with the same footprint is used, the calculated efficiency would be increased by 57% due to the increased surface area, or about 29.25%.

All publications, articles, papers, patents, patent publications, and other references cited herein are hereby incorporated by reference herein in their entireties for all purposes.

Although the foregoing description is directed to the preferred embodiments of the present teachings, it is noted that other variations and modifications will be apparent to those skilled in the art, and which may be made without departing from the spirit or scope of the present teachings. The provided FIGURES are not to scale, and the angles between various members of the apparatus are merely illustrative.

The foregoing detailed description of the various embodiments of the present teachings has been provided for the purposes of illustration and description. It is not intended to be exhaustive or to limit the present teachings to the precise embodiments disclosed. Many modifications and variations will be apparent to practitioners skilled in this art. The embodiments were chosen and described in order to best explain the principles of the present teachings and their practical application, thereby enabling others skilled in the art to understand the present teachings for various embodiments and with various modifications as are suited to the particular use contemplated. It is intended that the scope of the present teachings be defined by the following claims and their equivalents.

What we claim is:

1. A photovoltaic panel comprising:
a flat substrate;
at least one hemispherical shaped structure positioned on the flat substrate, and
a plurality of solar cells,
wherein the plurality of solar cells are adhered to and cover the at least one hemispherical shaped structure.

2. The photovoltaic panel according to claim 1, further comprising a round solar cell adhered at the top of the hemispherical shaped structure.

3. The photovoltaic panel according to claim 1, wherein the hemispherical shaped structure has a maximum diameter equal to the length of the flat substrate.

4. The photovoltaic panel according to claim 3, wherein the hemispherical shaped structure has at least 57% more surface area than the flat substrate.

5. The photovoltaic panel according to claim 1, wherein the solar cells are connected together electronically.

6. The photovoltaic panel according to claim 1, wherein the solar cells are one of more member selected from the group consisting of monocrystalline silicon-based solar cells, polycrystalline silicon-based solar cells, perovskite-based solar cells, photovoltaic organic-based solar cells, thin film solar cells, cadmium telluride-based solar cells, and copper indium gallium selenide-based solar cells.

7. The photovoltaic panel according to claim 1, wherein hemispherical shaped structure is composed of one or more material selected from the group consisting of silicon, polycarbonate, carbon fiber, aluminum, stainless steel, galvanized steel, fiberglass, composite materials, and titanium.

8. The photovoltaic panel according to claim 1, further comprising a coating layer on the solar cells and an outer surface of the at least one hemispherical shaped structure.

9. The photovoltaic panel according to claim 8, wherein the coating layer comprises ethylene-vinyl acetate.

10. The photovoltaic panel according to claim 1, wherein a plurality of hemispherical shaped structures are positioned on the flat substrate.

11. A method of preparing a hemispherical-shaped solar panel, comprising
providing a hemispherical-shaped forming plate;
providing a sheet of support material;
contacting the sheet of support material to the hemispherical-shaped forming plate;
conforming the support material to the hemispherical-shaped forming plate;
forming a hemispherical dome in the sheet of support based material, the hemispherical dome having an outer surface and an inner surface;
adhering solar cells to the outer surface of the hemispherical dome, and
electrically connecting the solar cells.

12. The method according to claim 11, further comprising
coating the adhered solar cells and the outer surface of the hemispherical dome with a protective coating.

13. The method according to claim 11, wherein the solar cells are one of more member selected from the group consisting of monocrystalline silicon-based solar cells, polycrystalline silicon-based solar cells, perovskite-based solar cells, photovoltaic organic-based solar cells, thin film solar cells, cadmium telluride-based solar cells, and copper indium gallium selenide-based solar cells.

14. The method according to claim 11, wherein the support material is composed of one or more material selected from the group consisting of silicon, polycarbonate, carbon fiber, aluminum, stainless steel, galvanized steel, fiberglass, composite materials, and titanium.

15. The method according to claim 11, wherein the hemispherical-shaped forming plate comprises a plurality of hemispherical domes.

16. The method according to claim 11, wherein the protective coating comprises a hydrophobic, scratch-resistant and self-cleaning coating.

17. The method according to claim 11, wherein the protective coating comprises a waterproof and UV-resistant ethylene-vinyl acetate.

18. A method of using a photovoltaic panel to generate electrical energy from the sun comprising:
providing a photovoltaic panel comprising a flat substrate, at least one hemispherical shaped structure positioned on the flat substrate, and a plurality of solar cells adhered to and covering the at least one hemispherical shaped structure;
positioning the photovoltaic panel to expose it to the maximum possible amount of sunlight for its location;
exposing the photovoltaic panel to sunlight, and
generating electrical energy from the photovoltaic panel.

19. The method according to claim 18, wherein the solar cells are one of more member selected from the group consisting of monocrystalline silicon-based solar cells, polycrystalline silicon-based solar cells, perovskite-based solar cells, photovoltaic organic-based solar cells, thin film solar cells, cadmium telluride-based solar cells, and copper indium gallium selenide-based solar cells.

20. The method according to claim 18, wherein the hemispherical shaped structure is composed of one or more material selected from the group consisting of silicon, polycarbonate, carbon fiber, aluminum, stainless steel, galvanized steel, fiberglass, composite materials, and titanium.
